(19) United States
(12) Patent Application Publication
(10) Pub. No.: US 2017/0256574 A1
(43) Pub. Date: Sep. 7, 2017

(54) Image-Sensing Device

(71) Applicant: Silicon Optronics, Inc., Hsinchu (TW)

(72) Inventor: Bo-Ray LEE, Hsinchu (TW)

(21) Appl. No.: 15/087,339

(22) Filed: Mar. 31, 2016

(30) Foreign Application Priority Data
Mar. 4, 2016 (TW) 105106649

(51) Int. Cl. H01L 27/146

(52) U.S. Cl. CPC H01L 27/1463; H01L 27/14643

(57) ABSTRACT

An image-sensing device includes a semiconductor substrate including an image-sensing region and a peripheral circuit region surrounding the image-sensing region. The image-sensing device further includes an image-sensing element disposed in the semiconductor substrate in the image-sensing region, and an imaging processing element disposed in the semiconductor substrate in the peripheral circuit region. The image-sensing device further includes a first isolation element disposed in the semiconductor substrate in the peripheral circuit region and adjacent to the image-sensing element in the image-sensing region. The first isolation element includes a metal portion having a coefficient of heat conduction greater than 149 W/m·K, and an imaginary part of a permittivity (Im(ε)) of the metal portion under a light wavelength of 1100 nm is greater than 0.004.

### CROSS REFERENCE TO RELATED APPLICATIONS

This Application claims priority of Taiwan Patent Application No. 105106649, filed on Mar. 4, 2016, the entirety of which is incorporated by reference herein.

### BACKGROUND OF THE INVENTION

Field of the Invention

The present invention relates to image-sensing devices, and in particular, to an image-sensing device comprising an isolation element disposed between an image-sensing region and a peripheral circuit region to reduce or prevent elements in the image-sensing region from being affected by elements in the peripheral circuit region.

Description of the Related Art

Image-sensing devices are necessary components in many optoelectronic devices, including digital cameras, cellular phones, and toys. Conventional image-sensing devices include both charge coupled device (CCD) image-sensing devices and complementary metal oxide semiconductor (CMOS) image-sensing devices.

Typically, an image-sensing device is a mixed-signal system having both analog circuits and digital circuits on a single device. The analog and digital circuits generate heat energy accumulations, and they may also become an infrared (IR) dipole light source after the long-term operation thereof, thereby becoming a heat source and/or a light source. The heat energy and/or the light energy that is generated may propagate to the sensing elements in the image-sensing region from the analog/digital circuits. Accordingly, the sensing elements in the image-sensing region are interfered with, and image noise such as light spots can be found in the displayed image. Thus the performance of the image-sensing device is adversely affected.

Therefore, a novel technique is needed to minimize or eliminate the aforementioned undesirable effects on the image-display performance of the image-sensing device, these effects having been caused by the heat energy or light energy generated by the analog and digital circuits of the image-sensing device.

### BRIEF SUMMARY OF THE INVENTION

An exemplary image-sensing device comprises a semiconductor substrate comprising an image-sensing region and a peripheral circuit region surrounding the image-sensing region. The image-sensing device further comprises an image-sensing element disposed in the semiconductor substrate in the image-sensing region, and an image-processing element disposed in the semiconductor substrate in the peripheral circuit region. The image-sensing device further comprises a first isolation element disposed in the semiconductor substrate in the peripheral circuit region and adjacent to the image-sensing element in the image-sensing region. The first isolation element comprises a metal portion having a coefficient of heat conduction greater than 149 W/m·K, and an imaginary part of a permittivity (Im(ε)) of the metal portion under a light wavelength of 1100 nm is greater than 0.004.

In one embodiment, the image-sensing device further comprises a second isolation element disposed in the semiconductor substrate in the peripheral circuit region, and disposed between the first isolation element and the image-processing element. The second isolation element comprises another metal portion having a coefficient of heat conduction greater than 149 W/m·K, and an imaginary part of a permittivity (Im(ε)) of the other metal portion under a light wavelength of 1100 nm is greater than 0.004.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic top view showing an image-sensing device according to an embodiment of the invention;

FIG. 2 is a schematic cross section of the image-sensing device taken along the line 2-2 in FIG. 1;

FIG. 3 is a schematic top view showing an image-sensing device according to another embodiment of the invention;

FIG. 4 is a schematic cross section of the image-sensing device taken along the line 4-4 in FIG. 3;

FIG. 5 is a schematic top view showing an image-sensing device according to yet another embodiment of the invention; and

FIG. 6 is a schematic cross section of the image-sensing device taken along the line 6-6 in FIG. 5.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

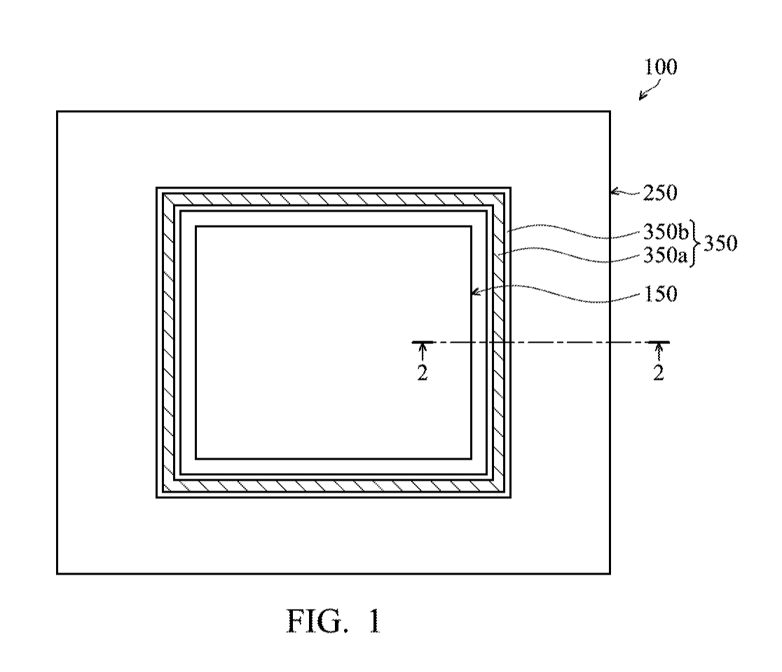

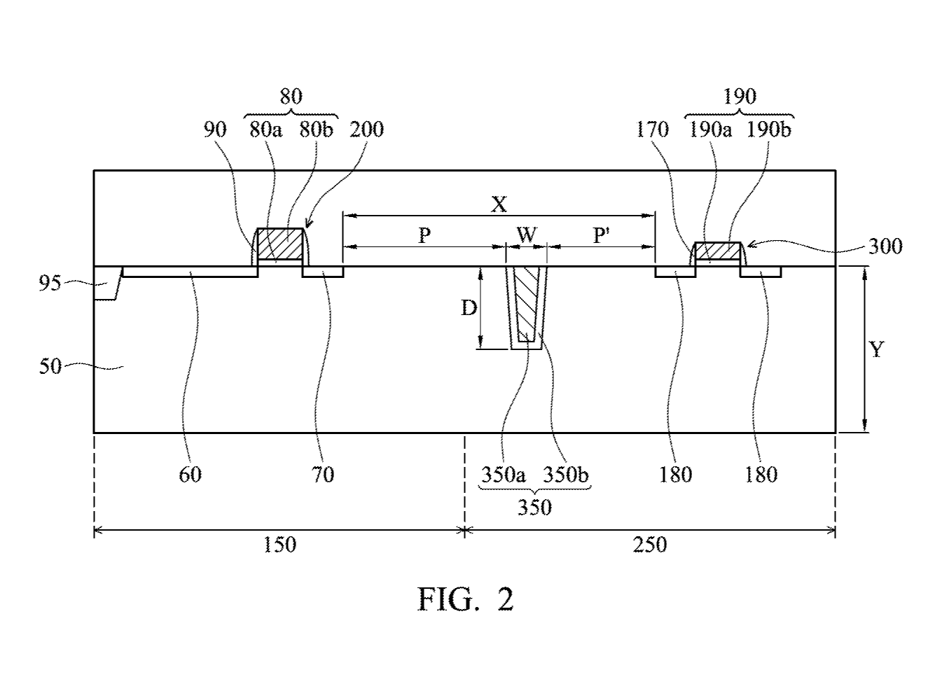

FIGS. 1-2 are schematic diagrams shown an image-sensing device 100 according to an embodiment of the invention, wherein FIG. 1 is a schematic top view of the image-sensing device 100 and FIG. 2 is a schematic cross section of the image-sensing device 100 taken along the line 2-2 in FIG. 1.

As shown in FIGS. 1-2, the image-sensing device 100 mainly comprises an image-sensing region 150 located at a central portion and a peripheral circuit region 250 disposed around the image-sensing region 150. A plurality of image-sensing elements (see FIG. 2) for image sensing are disposed in the image-sensing region 150, and a plurality of image-processing elements (see FIG. 2) such as analog and/or digital elements for image processing corresponding to the image-sensing elements in the image-sensing region 150 are disposed in the peripheral circuit region 250.

Referring to FIG. 2, the plurality of image-sensing elements in the image-sensing region 150 can be disposed in an array configuration (not shown). Herein, for purposes of easy description and simplicity of illustration, only one image-sensing element 200 in the image-sensing region 150 adjacent to the peripheral circuit region 250 is illustrated. The image-sensing element 200 can be, for example, photodiodes or the like.

As shown in FIG. 2, in one embodiment, the image-sensing element 200 in the image-sensing region 150 is illustrated as an active-type image-sensing element, which comprises a sensing region 60 and a source/drain region 70 formed in the semiconductor substrate 50. In addition, the image-sensing element 200 further comprises a gate structure 80 formed over the semiconductor substrate 50 between the sensing region 60 and the source/drain region 70, and a spacer 90 formed on opposite sidewalls of the gate structure 80. Moreover, an isolation element 95 is disposed in the semiconductor substrate 50 at a side adjacent to the sensing region 60 to isolate the image-sensing element 200 from another image-sensing element 200 (not shown) adjacent thereto.

In one embodiment, the semiconductor substrate can be a substrate such as a silicon wafer, and the sensing region 60 can be an image-sensing region having suitable doping properties. The gate structure 80 comprises a gate dielectric layer 80a and a gate electrode layer 80b over the gate dielectric layer 80a which are sequentially formed over the semiconductor substrate 50. In addition, the isolation element 95 can be, for example, a shallow trench isolation (STI).

In addition, still referring to FIG. 2, the peripheral circuit region 250 comprises a plurality of image-processing elements for processing sensed data from the plurality of image-sensing elements (e.g. the image-sensing elements 200) in the image-sensing region 150. Herein, for the purpose of easy description and to simplify the illustrations, only one image-processing element 300 in the peripheral circuit region 250 is illustrated.

As shown in FIG. 2, the image-processing element 300 in the peripheral circuit region 250 comprises a pair of source/drain regions 180 formed in the semiconductor substrate 50. In addition, the image-processing element 300 further comprises a gate structure 190 formed over the semiconductor substrate 50 between the pair of source/drain regions 180, and a spacer 170 formed on opposite sidewalls of the gate structure 190. In one embodiment, the image-processing element 300 can be an analog element and/or an digital element applied in a related circuit for image-processing. Herein, the gate structure 190 comprises a gate dielectric layer 190a and a gate electrode layer 190b over the gate dielectric layer 190a which are sequentially formed over the semiconductor substrate 50.

In addition, an isolation element 350 is disposed in the semiconductor substrate 50 at a place that is adjacent to the image-sensing element 200 in the image-sensing region 150 to isolate the image-sensing element 200 from the adjacent image-processing element 300 in the peripheral circuit region 250. Herein, compared with the isolation element 95 in the image-sensing region 150, the isolation element 350 has a deeper depth D in the semiconductor substrate 50, and the isolation element 350 is a distance P away from the image-processing element 300 in the peripheral circuit region 250. In addition, the isolation element 350 is a distance P′ away from the image-processing element 300 in the peripheral circuit region 250, and the image-processing element 300 in the peripheral circuit region 250 is a distance X away from the image-sensing element 200 in the image-sensing region 150. Moreover, the semiconductor substrate 50 has a thickness Y.

In an embodiment, the isolation element 350 shown in FIG. 2 has a width W greater than at least 0.5 μm. Herein, the isolation element 350 comprises a metal portion 350a and an insulating liner layer 350b formed between the metal portion 350a and the semiconductor substrate 50. The metal portion 350a may have a coefficient of heat conduction greater than 149 W/m·K, and the imaginary part of the permittivity (Im(ε)) of the metal portion 350a under a light wavelength of 1100 nm is greater than 0.004. In one embodiment, the metal portion 350a of the isolation element 350 may comprise aluminum, tungsten, copper, titanium or the like, and the insulating liner layer 350b of the isolation element 350 may comprise silicon oxide, silicon oxynitride, silicon nitride, or the like. The insulating liner layer 350b of the isolation element 350 may have a thickness of at least 50 Å. The insulating liner layer 350b of the isolation element 350 may isolate the metal portion 350a of the isolation element 350 from the semiconductor substrate 50, such that the metal portion 350a is prevented from contacting the semiconductor substrate 50, thereby preventing increases of dark currents.

In one embodiment, fabrications of the metal portion 350a and the insulating liner layer 350b of the isolation element 350 can be formed by semiconductor fabrications such as photolithography, etching, and film deposition and processing (not shown). The isolation element 350 can be formed before, during, or after fabrication of the image-sensing element 200 and the image-processing element 300 based on designs of the image-sensing device 100.

Referring to FIG. 1, a schematic top view of the image-sensing device 100 shown in FIG. 2 is illustrated, and FIG. 2 shows a schematic cross section taken along line 2-2 in FIG. 1. As shown in FIG. 1, the isolation element 350 comprising the metal portion 350a and the insulating liner layer 350b is illustrated with a continuous configuration entirely surrounding the image-sensing region 150.

As shown in FIGS. 1-2, in one embodiment, the thickness Y of the semiconductor substrate 50, the distance P from the isolation element 350 to the image-sensing element 200 in the image-sensing region 150, the distance P′ from the isolation element 350 to the image-processing element 300 in the periphery circuit region 250, and the distance X from the image-processing element 300 in the periphery circuit region 250 to the image-sensing element 200 in the image-sensing region 150 may satisfy the following equation (1):

D/P═≧Y/X (1)

While heat-energy generated and/or an infrared (IR) dipole light source is formed due to the long-term operation of the image-processing element 300 in the peripheral circuit region 250, the generated heat-energy and/or light energy may propagate from the peripheral circuit region 250 toward the image-sensing region 150 through the semiconductor substrate 50. However, compared to the semiconductor material (e.g. silicon) of the semiconductor substrate 50, since the metal materials used for the metal portion 350a of the isolation element 350 have better heat dissipation properties and light-absorption properties, the heat-energy that is generated can be dissipated by the isolation element 350 itself. Radiation such as infrared light emitted from the image-processing element 300 can also be blocked by the light-absorption properties of the metal materials. In addition, due to the width of the isolation element 350 being greater than at least 0.5 μm and the conditions of the distance P from the isolation element 350 to the image-sensing element 200 in the image-sensing region 150, the distance P′ from the isolation element 350 to the image-processing element 300 in the periphery circuit region 250, and the distance X from the image-processing element 300 in the periphery circuit region 250 to the image-sensing element 200 in the image-sensing region 150 in the above equation (1), the possibility of light energy infrared light that propagated from the image processing region 250 to the image-sensing region 150 can be prevented. Therefore, the thermal energy that propagates from the peripheral circuit region 250 toward the image-sensing region 150 can be reduced or prevented, and the light energy that propagates from the peripheral circuit region 250 toward the image-sensing region 150 can be shielded, thereby reducing or preventing thermal energy and/or light energy produced by the circuit elements such as the image-processing element 300 in the peripheral circuit region 250 from affecting the image-sensing element such as image-sensing element 200 in the image-sensing region 150, and ensuring image performance of the image-sensing device 100. Therefore, no undesired image noise such light spot will be presented in the image-sensing region 150.

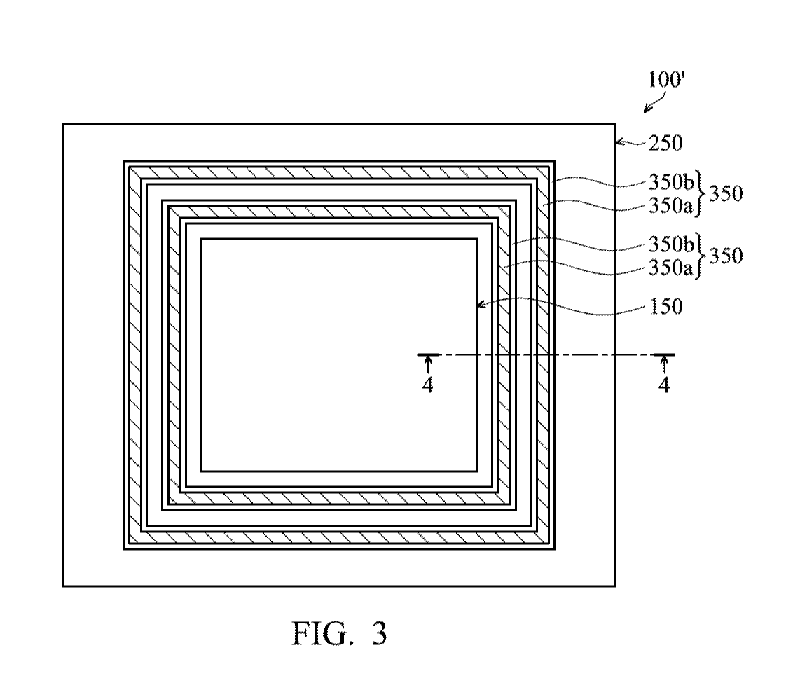

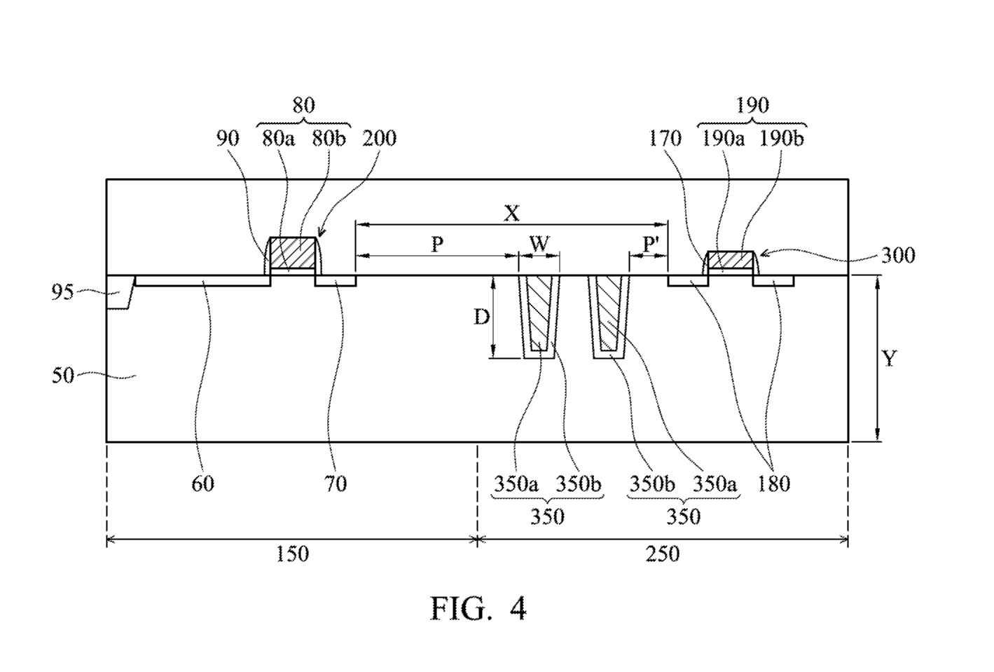

However, the isolation element of the invention is not limited to the isolation element 350 shown in FIGS. 1-2. FIGS. 3-4 are schematic diagrams showing an image-sensing device 100′ according to another embodiment of the invention, wherein FIG. 3 is a schematic top view, and FIG. 4 is a schematic cross section of an image-sensing device 100′ taken along the line 4-4 in FIG. 3.

Herein, the image-sensing device 100′ shown in FIGS. 3-4 is modified from the image-sensing device 100 shown in FIGS. 1-2. The same reference numbers shown in FIGS. 1-2 and FIGS. 3-4 represent the same elements, and only differences between the image-sensing devices 100 and 100′ are discussed below.

Referring to FIGS. 3-4, similar to those shown in FIGS. 1-2, another isolation element 350 can additionally be disposed between the isolation element 350 in the peripheral circuit region 250 and the image-processing element 300 to further reduce or prevent thermal energy propagating from the peripheral circuit region 250 toward the image-sensing region 150, and to shield the light energy that propagates from the peripheral circuit region 250 toward the image-sensing region 150, thereby reducing or preventing thermal energy and/or light energy produced by the circuit elements such as the image-processing element 300 in the peripheral circuit region 250 from affecting the image-sensing element such as image-sensing element 200 in the image-sensing region 150, and ensuring image performance of the image-sensing device 100′. Therefore, no undesired image noise such as light spot will be presented in the image-sensing region 150. As shown in FIG. 3, these two isolation elements 350 are illustrated as continuous isolation elements both entirely surrounding the image-sensing region 150.

In one embodiment, similar to those disclosed in FIGS. 1-2, each of the isolation elements 350 may have a depth D, and each of the isolation elements 350 may have a width W of about 0.5 μm. The additional isolation element 350 is a distance P′ away from the adjacent image-processing element 300 in the periphery circuit region 250, and the thickness Y of the semiconductor substrate 50, a distance P from the left isolation element 350 to the image-sensing element 200 in the image-sensing region 150, a distance P′ from the right isolation element 350 to the image-processing element 300 in the periphery circuit region 250, and a distance X from the image-processing element 300 in the periphery circuit region 250 to the image-sensing element 200 in the image-sensing region 150 may satisfy the following equation (2):

D/P′≧Y/X (2)

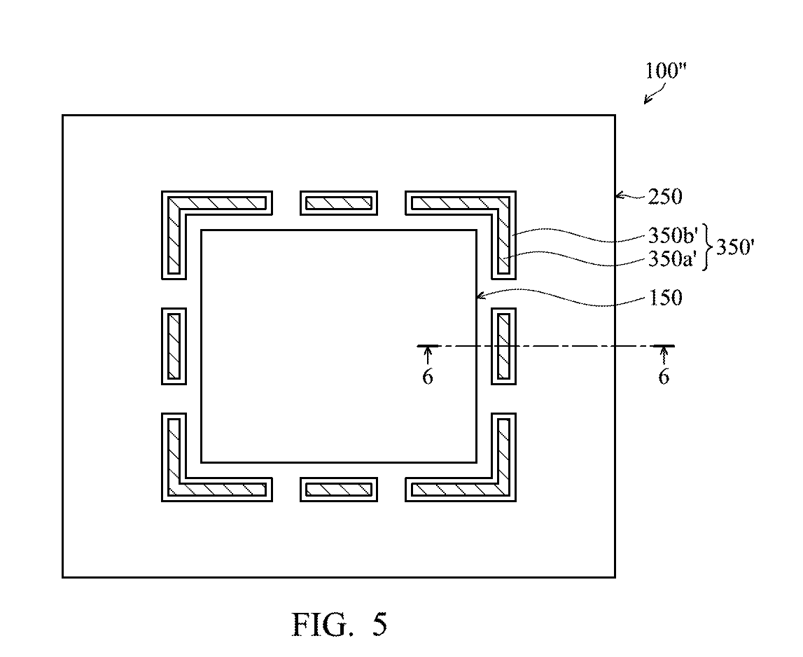

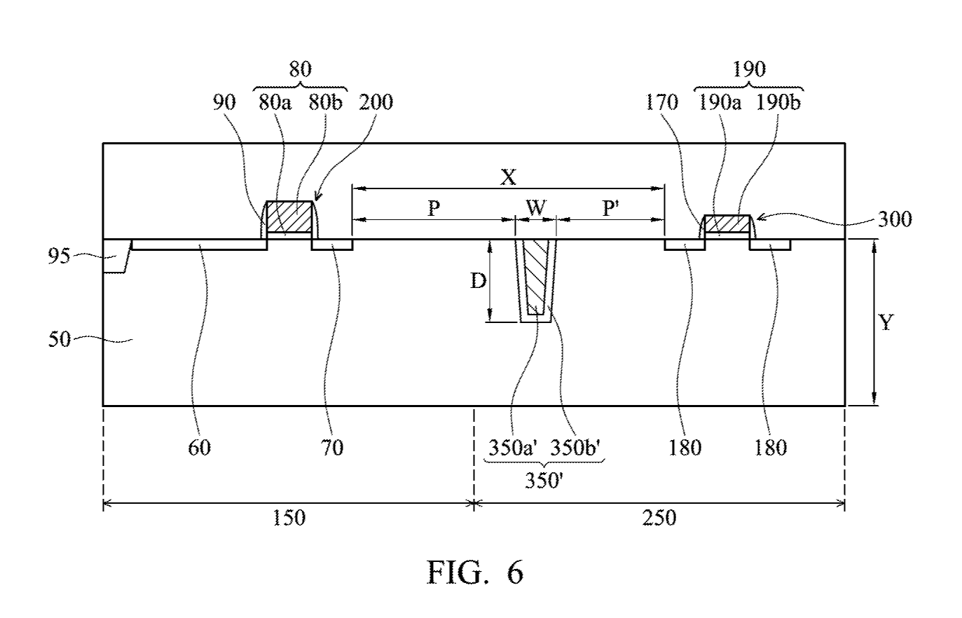

FIGS. 5-6 are schematic diagrams showing an image-sensing device 100″ according to yet another embodiment of the invention, wherein FIG. 5 is a schematic top view, and FIG. 6 is a schematic cross section of an image-sensing device 100″ taken along line 6-6 in FIG. 5.

Herein, the image-sensing device 100″ shown in FIGS. 5-6 is modified from the image-sensing device 100 shown in FIGS. 1-2. The same reference numbers shown in FIGS. 1-2 and FIGS. 5-6 represent the same elements, and only differences between the image-sensing devices 100 and 100″ are discussed below.

Referring to FIGS. 5-6, the continuous isolation element 350 entirely surrounding the image-sensing region 150 shown in FIGS. 1-2 are now modified as non-continuous isolation element 350′. Therefore, the isolation element 350′ used in FIGS. 5-6 are made of a plurality of discontinuous segments, and the adjacent segments of the isolation elements 350 are isolated from each other by the semiconductor substrate 50. Preferably, the non-continuous segments forming the isolation element 350′ surround the four corners of the image-sensing region 150.

As shown in FIGS. 5-6, similar to the isolation element 350, the isolation element 350′ may comprise a metal portion 350a′ and an insulating liner layer 350b′ formed between the metal portion 350a′ and the semiconductor substrate 50. Herein, materials and fabrications of the metal portion 350a′ and the insulating liner layer 350b′ are similar to materials and fabrications of the metal portion 350a and the insulating liner layer 350b that were mentioned previously, so that the segments forming the isolation element 350′ can still reduce or prevent thermal energy from propagating from the peripheral circuit region 250 toward the image-sensing region 150, and to shield the light energy that propagates from the peripheral circuit region 250 toward the image-sensing region 150, thereby reducing or preventing thermal energy and/or light energy produced by the circuit elements such as the image-processing element 300 in the peripheral circuit region 250 from affecting the image-sensing element such as image-sensing element 200 in the image-sensing region 150. Therefore, no undesired image noise such as light spot will be presented in the image-sensing region 150, and image performance of the image-sensing device 100″ can be ensured.

In addition, in other embodiments (not shown), configurations of the isolation elements 350 and 350′ shown in FIGS. 1-6 can be properly adjusted and arranged according to designs of the circuit elements in the peripheral circuit region 250. Suitable combinations of the isolation elements 350 and 350′ can be applied to reduce or prevent thermal energy from propagating from the peripheral circuit region 250 toward the image-sensing region 150, and to shield the light energy that may propagate from the peripheral circuit region 250 toward the image-sensing region 150, thereby reducing or preventing thermal energy and/or light energy produced by the circuit elements such as the image-processing element 300 in the peripheral circuit region 250 from affecting the image-sensing element such as image-sensing element 200 in the image-sensing region 150. Therefore, no undesired image noise such as light spots will be presented in the image-sensing region 150, and image performance of the image-sensing device can be ensured. The isolation elements 350 and 350′ shown in FIGS. 1-6 are not used to limit the scope of the invention.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. An image-sensing device, comprising:
a semiconductor substrate comprising an image-sensing region and a peripheral circuit region surrounding the image-sensing region;
an image-sensing element disposed in the semiconductor substrate in the image-sensing region;
an image-processing element disposed in the semiconductor substrate in the peripheral circuit region; and
a first isolation element disposed in the semiconductor substrate in the peripheral circuit region and adjacent to the image-sensing element in the image-sensing region, wherein the first isolation element comprises a metal portion, and wherein the metal portion is aluminum, tungsten, copper or titanium, and wherein the first isolation element is laterally spaced apart from the image-processing element.

2. The image-sensing device as claimed in claim 1, wherein a first distance is measured from an outer edge of the first isolation element to an outer edge of the image-processing element, a second distance is measured from an outer edge of the image-sensing element to the outer edge of the image-processing element, a first depth is measured from a top surface of the semiconductor substrate to a bottom surface of the first isolation element, and a first thickness is measured from the top surface of the semiconductor substrate to a bottom surface of the semiconductor substrate, wherein the first distance, the second distance, the first depth and the first thickness satisfy the following equation:
the first depth/the first distance≧the first thickness/the second distance.

3. (canceled)

4. The image-sensing device as claimed in claim 1, wherein the image-sensing element comprises a photodiode.

5. The image-sensing device as claimed in claim 1, wherein the image-processing element comprises an analog element or a digital element.

6. The image-sensing device as claimed in claim 1, wherein the first isolation element entirely surrounds the image-sensing region from a top view.

7. The image-sensing device as claimed in claim 1, wherein the first isolation element partially surrounds the image-sensing region from a top view.

8. The image-sensing device as claimed in claim 7, wherein the first isolation element surrounds a corner of the image-sensing region.

9. The image-sensing device as claimed in claim 1, further comprising a second isolation element disposed in the semiconductor substrate in the peripheral circuit region and disposed between the first isolation element and the image-processing element, wherein the second isolation element comprises another metal portion, and wherein the another metal portion is aluminum, tungsten, copper or titanium.

10. The image-sensing device as claimed in claim 9, wherein a third distance is measured from an outer edge of the second isolation element to an outer edge of the image-processing element, a second distance is measured from an outer edge of the image-sensing element to the outer edge the image-processing element, a second depth is measured from a top surface of the semiconductor substrate to a bottom surface of the second isolation element, a first thickness is measured from the top surface of the semiconductor substrate to a bottom surface of the semiconductor substrate, wherein the third distance, the second distance, the second depth and the first thickness satisfy the following equation:
the second depth/the third distance≧the first thickness/the second distance.

11. (canceled)

12. The image-sensing device as claimed in claim 9, wherein the second isolation element entirely surrounds the first isolation element and the image-sensing region from a top view.
